(19) United States
(12) Patent Application Publication
(10) Pub. No.: US 2015/0116996 A1
(43) Pub. Date: Apr. 30, 2015

(54) Electric Lamps and Methods of Manufacture of Electrical Devices

(71) Applicant: Nigel Alastair Dent, Oxford (GB)

(72) Inventor: Nigel Alastair Dent, Oxford (GB)

(73) Assignee: ZETA SPECIALIST LIGHTING LIMITED, Bicester (GB)

(21) Appl. No.: 14/379,673

(22) PCT Filed: Feb. 21, 2012
(86) PCT No.: PCT/GB2012/050379

§ 371 Date: Dec. 10, 2014

(51) Int. Cl. F21V 23/06; H05K 3/32; F21V 29/70

(52) U.S. Cl. CPC F21V 23/06; F21V 29/70; H05K 3/32; F21Y 2101/02
USPC 362/227; 29/832

(57) ABSTRACT

An electric lamp (10) comprises: a plurality of electrically-powered light sources (such as LEDs 34); at least one electrical connector (35) electrically connected to the light sources; and a structure to which the light sources are mounted with different orientations and to which the connector(s) is/are mounted. The structure has the form of an open, three-dimensional arrangement of, preferably metallic, interconnected mounting portions (21) with gaps therebetween so that ambient air can pass through the gaps and circulate through the arrangement of mounting portions. The light sources are mounted in thermal contact with the mounting portions. The mounting portions are thermally conductive so that they can dissipate heat away from the light sources. By mounting the light sources on and in thermal contact with a thermally conductive structure, heat can readily be dissipated from the light sources, and by arranging the mounting portions three-dimensionally, the light sources can conveniently be oriented in different directions.

This invention relates to electric lamps and to methods of manufacture of electrical devices. The invention was conceived while developing a ‘low-energy’ replacement for a conventional 60 Watt general lighting service (‘GLS’) tungsten-filament light bulb. However, the invention is also applicable to many other general types of electric lamp.

It is well known that the light-producing efficiency of tungsten-filament bulbs is low and that light-emitting diodes (‘LEDs’) can nowadays be produced having a far higher light-producing efficiency. However, despite producing significantly less heat than tungsten filament bulbs having the same light output, it is very important that the junction temperature of an LED is maintained below a limit value, otherwise the LED will immediately blow. Furthermore, even if an LED is operated with its junction below its limit temperature, its life expectancy decreases with increasing operating temperature. Moreover, the light-producing efficiency of LEDs decreases with increasing operating temperature.

It is also well known that a GLS bulb has a fairly uniform light radiation pattern over a very large angle, for example from 0 to 150 degrees or more relative to the axis of the bulb. By contrast, LEDs generally have a far smaller radiation angle unless special optics are provided. Furthermore, the light output from a single commonly-available high-power LED is substantially less than from a 60 Watt tungsten-filament bulb.

One way of emulating a GLS tungsten-filament using LED technology would therefore be to mount a number of LEDs in a cluster with the LEDs pointing in different directions. However, mounting the LEDs in a cluster increases the difficulty in dissipating heat from the LEDs so as to keep their junction temperatures low. Also, mounting a large number of LEDs in a cluster so that they face in different directions creates manufacturing difficulties.

An aim of a first aspect of the present invention, or at least of specific embodiments of it, is to produce an electric lamp which has a plurality of light sources oriented in different directions, which facilitates cooling of the light sources, and which can be manufactured relatively simply and inexpensively.

In accordance with the first aspect of the present invention, there is provided an electric lamp comprising: a plurality of electrically-powered light sources (for example LEDs); at least one electrical connector electrically connected to the light sources; and a structure to which the light sources are mounted with different orientations and to which the connector(s) is/are mounted. The invention is characterised in that: the structure has the form of an open, three-dimensional arrangement of interconnected mounting portions with gaps therebetween so that ambient air can pass through the gaps and circulate through the arrangement of mounting portions; the light sources are mounted in thermal contact with the mounting portions; and the mounting portions are thermally conductive so that they can dissipate heat away from the light sources.

By mounting the light sources on and in thermal contact with the arrangement of thermally conductive mounting portions, heat can readily be dissipated from the light sources, and by arranging the mounting portions three-dimensionally, the light sources can conveniently be oriented in different directions.

The light sources are preferably substantially rigidly mounted on the mounting portions. The structure is preferably substantially rigid. At least some of the mounting portions are preferably formed of metal. At least some of the mounting portions are preferably integrally formed. These features result in a robust structure.

In some embodiments, at least some of the mounting portions are integrally formed from an initially flat piece of material. At least some of the mounting portions may carry electrically-conductive tracks connecting at least in part the light sources to the electrical connector(s). Fitting the light sources to the flat piece of material before it is formed into the three-dimensional structure can simplify manufacture of the lamp.

The structure may have the form of an open, three-dimensional skeleton. Additionally or alternatively, the structure may have the form of a shell with apertures therethrough. The shell may be constructed from a plurality of separately formed shell portions, for example formed by die-casting or by pressing and forming sheet material.

Each of the light sources preferably has a rear face which is substantially flat and is mounted on a respective substantially flat part of such a mounting portion. This can simplify manufacture of the light sources and assembly of the lamp.

In some embodiments of the invention, the light sources are substantially regularly arranged around the axis of the lamp. In some embodiments of the invention, the optical axes of all or at least one group of the light sources extend substantially at right angles to the axis of the lamp. In this case, the lamp can be arranged to emulate a tube light or festoon bulb.

Alternatively or additionally, the optical axes of all or at least a first group of the light sources lie substantially on a first common cone. In some embodiments, the axis of the first common cone is substantially coaxial with the axis of the lamp. In some embodiments, the optical axes of a second group of the light sources lie substantially on a second common cone substantially coaxial with the first common cone. With these features, the lamp can be arranged to emulate a GLS bulb or a spotlight.

The lamp is preferably devoid of an enclosure enveloping the light sources, so as not to hinder the circulation of air. When used with a lamp fitting, the lamp fitting is preferably also devoid of an enclosure enveloping the light sources of the lamp.

An aim of a second aspect of the present invention, or at least of specific embodiments of it, is to produce an electric lamp that can have its light emitting devices mounted in an arrangement that can emulate a GLS light bulb and yet enables the lamp to be manufactured simply and inexpensively.

In accordance with the second aspect of the present invention, there is provided a method of manufacture of an electric lamp comprising the steps of: providing at least two shell portions and a circuit board; assembling the shell portions and the circuit board so that the shell portions are mechanically connected to each other to form a hollow shell, the circuit board is contained within the shell, and an electrical input to the circuit board is externally accessible; attaching a plurality of light emitting devices to the shell; and electrically connecting the light emitting devices to the circuit board. As in the case of the embodiment of the invention that will be described below, the shell may have an approximately pear-shaped outline, with one of the shell portions being approximately hemispherical and forming the blunt end of the pear shape, and the other shell portion forming the remainder of the pear shape.

The attaching step preferably involves attaching a respective plurality of the light emitting devices to each of the shell portions. The light emitting devices may be arranged in any suitable arrangement on the pear-shaped shell, but it has been found that by mounting five light emitting devices symmetrically around the axis of the pear shape and having their primary axes inclined towards the blunt end of the pear shape, and by mounting a further five light emitting devices symmetrically around the axis of the pear shape and having their primary axes inclined away the blunt end of the pear shape, a very satisfactory light distribution can be achieved.

In order to facilitate the electrical connection of the light emitting devices to the circuit board, the method preferably further includes the step of fitting at least one electrical distribution device to at least one of the shell portions, and the electrically-connecting step preferably comprises electrically connecting the electrical distribution device(s) to the circuit board and to the light emitting devices.

The light emitting devices may be soldered to the distribution device, but in order to facilitate automated assembly the distribution device and the light emitting devices preferably have complementary push-fit electrical connecting elements. More preferably, the connecting elements have barbed features so that they can be readily connected during manufacture, but cannot be readily disconnected.

The step of mechanically connecting the shell portions together may include the step of deforming locking elements of the shell portions into locking engagement, the locking elements being disposed inside the shell and being deformed by at least one tool inserted through at least one aperture in the shell. Alternatively or additionally, the shell portions may be bonded together.

The shell portions may be formed by die casting metal, or by pressing and forming sheet metal. In either case, the metal is preferably aluminium alloy.

The method may further include the steps of: providing a connector cap having at least two electrical terminals; mechanically connecting the connector cap to one of the shell portions; and electrically connecting the electrical terminals to the circuit board. Alternatively, one of the shell portions may be formed with a connector cap having at least two electrical terminals, and the method may further include the step of electrically connecting the electrical terminals to the circuit board.

An aim of a third aspect of the present invention, or at least of specific embodiments of it, is to produce an electrical device that has components mounted in a complex arrangement, and to enable the device to be manufactured simply and inexpensively.

In accordance with the third aspect of the present invention, there is provided a method of manufacture of an electrical device, comprising the steps of: providing a flat, plastically-deformable circuit board; then mounting at least one electrical component (for example at least one LED) on the flat circuit board and electrically connecting the component(s) in a circuit; and then plastically deforming the circuit board so that it is no longer flat, and the component(s) remain(s) mounted on the circuit board and electrically connected in the circuit.

Mounting the electrical component(s) on the circuit board while it is flat simplifies manufacture, and then deforming the circuit board enables complex shapes to be produced.

The mounting and connecting step may include mounting the component or at least one of the components on the circuit board, and then electrically connecting that component or those components with wires.

However, in order to facilitate automation of the method, the circuit board preferably has a plurality of deformable, electrically-conductive tracks formed on a plastically-deformable substrate, and the mounting and connecting step preferably includes physically and electrically connecting the component or at least one of the components to the tracks. In this case, the tracks are preferably disposed on the substrate so that none of the tracks undergoes sufficient elongation to cause the tracks to break during the deforming step. In order to facilitate this, at least one through-hole may be formed in the substrate, with at least two of the tracks being connected through the hole. The tracks can therefore be arranged to that they are, for example, always on the inside of a bend in the substrate. In the case where the substrate is electrically conductive, an electrically-insulating layer is disposed between each track and the substrate.

The circuit board, or at least the substrate thereof, is preferably thermally conductive to facilitate heat dissipation from the electrical components and/or is preferably formed of metal, such as aluminium or copper.

During the deforming step, the circuit board may be folded and/or bent. More particularly, a portion of the circuit board may be folded or bent in a first direction, and then a portion of the circuit board may be folded or bent in a second direction not parallel to the first direction. The circuit board may be formed with at least one slit such that, during the deforming step, the width of the slit increases. It is therefore possible to form the circuit board into interesting shapes. In particular, the circuit board may be formed with a plurality of slits between portions of the circuit board such that, during the deforming step, the widths of the slits increase so that after the deforming step those portions of the circuit board form an open skeleton, for example a three-dimensional skeleton.

During the deforming step, a portion of the circuit board may bent so that it becomes substantially tubular.

In accordance with a fourth aspect of the invention, there is provided an electrical device (such as an electric lamp) manufactured by the method of the second or third aspect of the invention.

Specific embodiments of the present invention will now be described, purely by way of example, with reference to the accompanying drawings, in which:

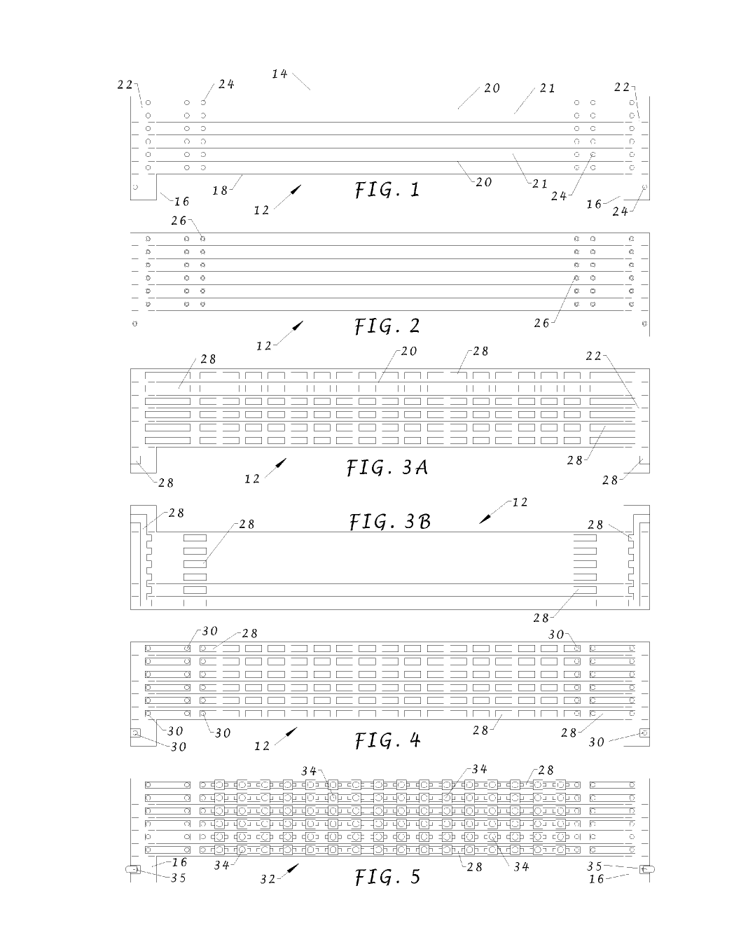

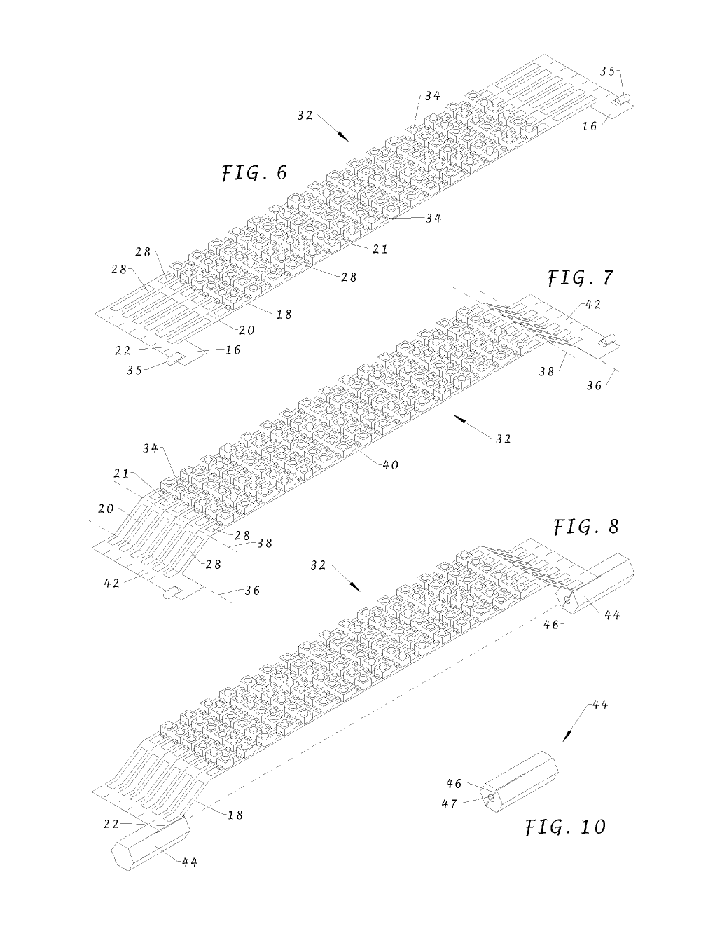

FIGS. 1-9 show various stages in the manufacture of a first embodiment of electric lamp, with FIGS. 1-5 being plan views and FIGS. 6-9 being isometric views;

FIG. 10 is an isometric view of a former used in the manufacture of the electric lamp;

FIG. 11 is an isometric view of the completed electric lamp;

FIG. 12 is a side view of the electric lamp, cross-sectioned on its it right half;

FIG. 13 is a cross-sectioned end view of the electric lamp;

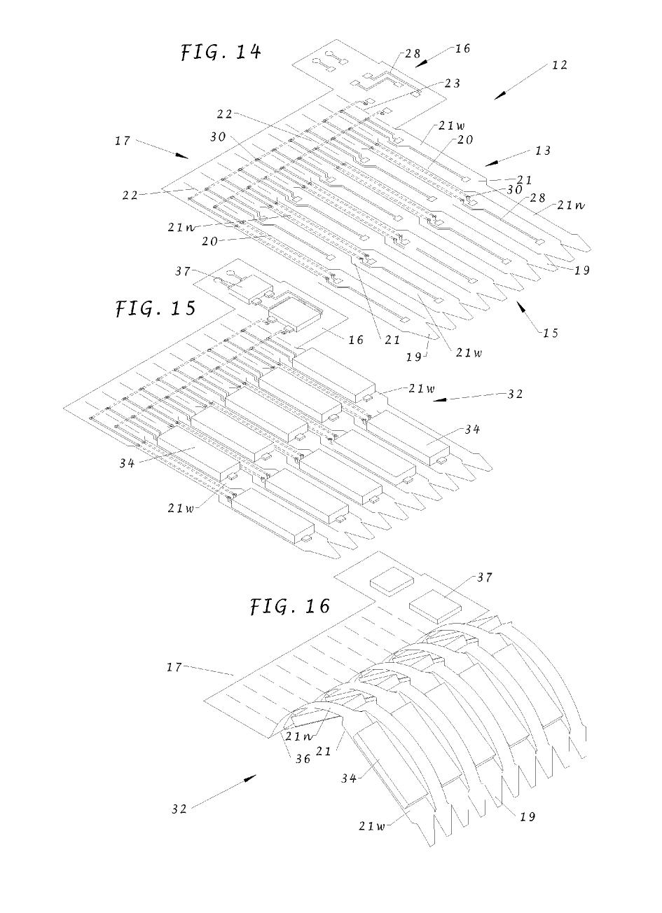

FIGS. 14-18 are isometric views showing various stages in the manufacture of a second embodiment of electric lamp;

FIG. 19 is an isometric view of a former used in the manufacture of the electric lamp;

FIG. 20 is an isometric view of the completed electric lamp;

FIG. 21 is a side view of the electric lamp, cross-sectioned on its it right half;

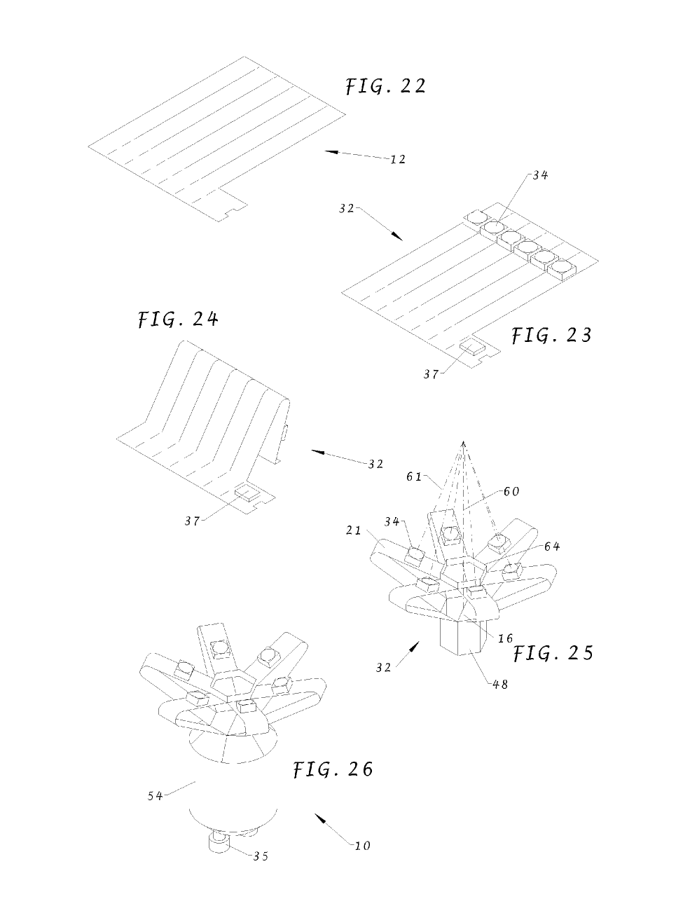

FIGS. 22-26 are isometric views showing various stages in the manufacture of a third embodiment of electric lamp;

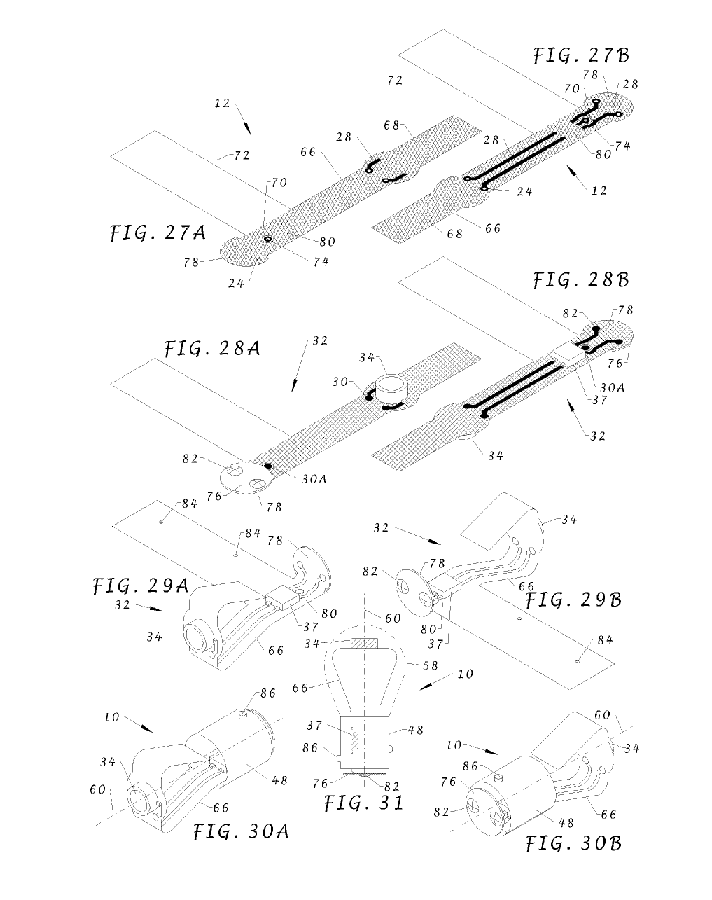

FIGS. 27-30 are isometric views showing various stages in the manufacture of a fourth embodiment of electric lamp;

FIG. 31 is a sectioned side view of the fourth embodiment of electric lamp;

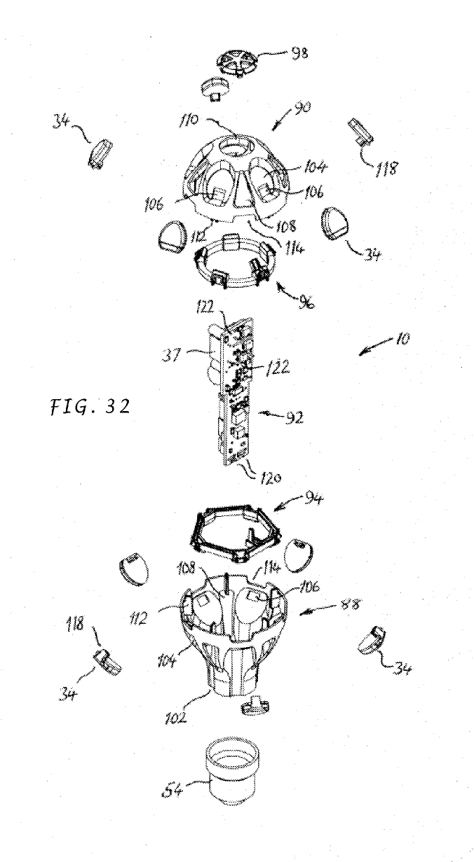

FIG. 32 is an exploded isometric view of a fifth embodiment of electric lamp;

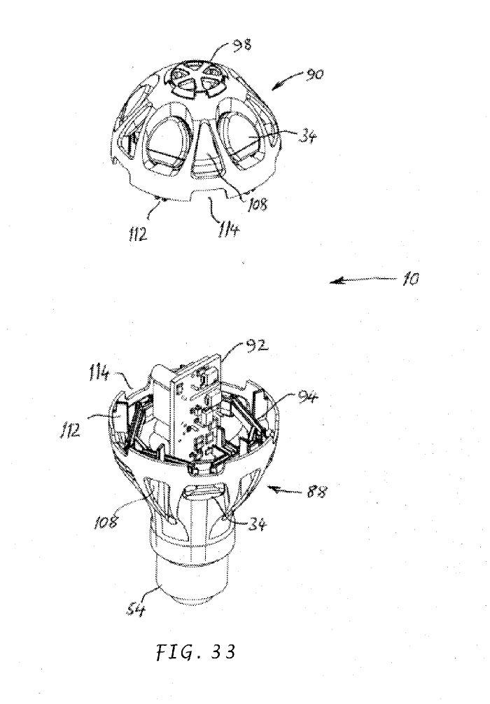

FIG. 33 is an isometric view of the lamp of FIG. 32 partly assembled; and

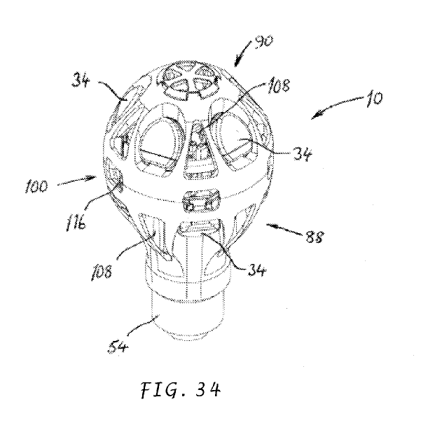

FIG. 34 is an isometric view of the lamp of FIG. 32 fully assembled.

Referring to the drawings, in the manufacture of the first embodiment of electric lamp 10 (FIGS. 11-13) emulating a conventional tube or festoon light bulb, a blank 12 (FIG. 1) is employed comprising a flat sheet of aluminium having a thickness of, for example, 1 to 2 mm and to each face of which is bonded an electrically-insulating layer of, for example, Melinex® polyethylene terephthalate film. The blank 12 is cut to have a main rectangular portion 14 and a pair of smaller rectangular tabs 16 projecting from one edge 18 of the main portion 14 at the ends of that edge 18. Five equispaced main slits 20 are formed through the main portion 14 parallel to the edge 18 between the tabs 16 to divide the main portion into six parallel ribs 21. The main slits 20 and the edge 18 are continued as dashed slits 22 at the ends of the main portion 14. A number of though-holes 24 are formed in the blank 12.

Referring to FIG. 2, each through-hole 24 in the blank 12 is then lined with an electrically-insulating sleeve 26 of plastics material.

Referring to FIGS. 3A-B, which show the opposite faces of the blank 12, a number of copper tracks 28 are then formed on the insulating layers of the blank 12 in a required pattern. The tracks 28 cover both ends of each of the lined holes 24 but do not cover any of the slits 20,22. The copper tracks 28 may be applied in any suitable manner, for example by blanking-out copper foil and bonding the pieces to the insulated blank 12, or by a foil blocking process.

Referring to FIG. 4, a number of headed copper rivets 30 are then punched through the insulated through-holes 24 and the copper tracks 28 at either end of them, and the tails of the rivets 30 are upset so that the rivets 30 form vias electrically connecting the tracks 28 at each end of each hole 24.

Referring to FIGS. 5-6, the assembly of the circuit board 32 is completed by soldering a number of electrical components onto the blank 12. The components include surface-mount LEDs 34 which are connected between portions of adjacent tracks 28 and two brass connection terminals 35 which are connected to the tracks 28 on the tabs 16. Preferably the components 34,35 are soldered using a wave-soldering technique. Thermally conductive paste or pads may be placed between the LEDs 34 and the circuit board 32.

It will be noted from a study of FIGS. 1-5 that the circuit board 32 provides six parallel electrical sub-circuits between the terminals 35, each sub-circuit including a respective row of sixteen of the LEDs 34 daisy-chained in series and mounted on a respective one of the ribs 21. At this stage of the manufacture, the circuit board 32 may be tested by connecting an electrical supply to the terminals 35.

It will also be noted that the manufacture of the circuit board 32 so far, including completion of the electrical circuitry, has been done on the flat, so that highly automated techniques can readily be employed.

For simplicity, in FIGS. 6-12 the heads and tails of the rivets 30 have not been shown.

Referring now to FIGS. 6-7, the circuit board 32 is then folded in a press between suitable dies along four parallel fold lines 36,38 at right-angles to the main slits 20. The fold lines 36 are at the ends of the slits 20, whereas the fold lines 38 are part way along the ribs 21 before the endmost LEDs 34 in the rows. During and after bending, the main portions 40 of the ribs 21 carrying the LEDs 34 remain planar. After bending, the two end portions 42 of the circuit board 32 beyond ends of the main slits 20 are coplanar in a plane parallel to the main portions 40 of the ribs 21. From a study of FIGS. 3A-B and 7, it will be noted that copper tracks 28 remain flat or are disposed on the insides of the folds so that the tracks 28 are not elongated during the bending process.

In the next step, a pair of formers 44 as shown in FIG. 10 is employed. Each former 44 comprises a bar of hexagonal cross-section, where the length of side of the hexagon is slightly less than the width of each rib 21 of the circuit board 32. A diametric slot 46 is formed in one end of the former and has a width slightly larger than the thickness of the circuit board 32. The slots 46 are relieved (at 47) so as not to foul the terminals 35.

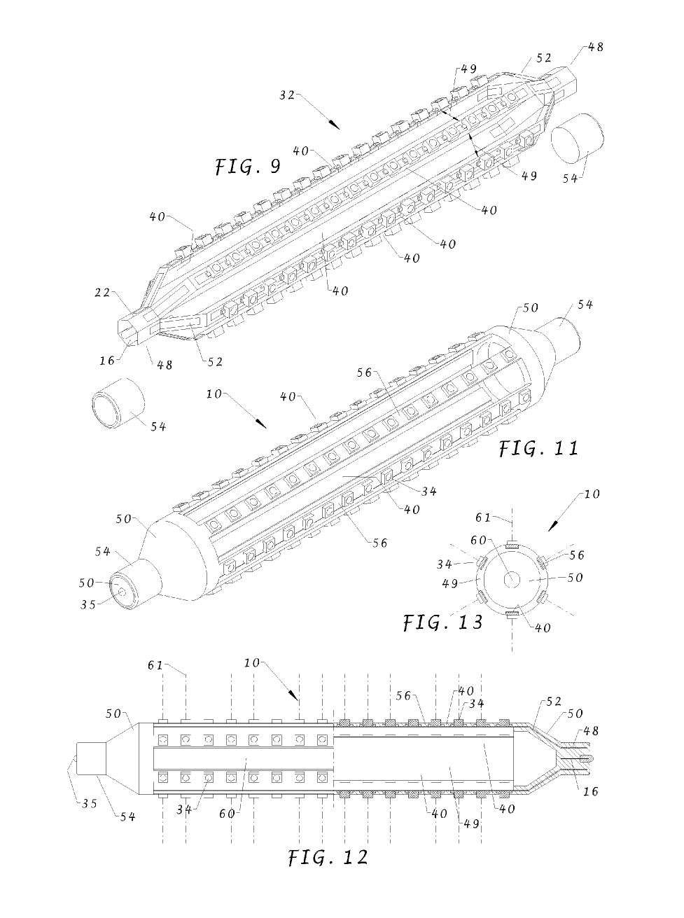

With the formers 44 coaxial and suitably spaced, the tabs 16 of the circuit board 32 are fitted into the slots 46 of the formers 44 and then folded, as shown in FIG. 8, relative to the remainder of the circuit board 32 through an angle of 120 degrees along the line of the dashed slits 22 aligned with the edge 18 of the circuit board 32. These dashed slits 22 assist in producing a sharp fold. Then, the end portions 42 of the circuit board 32 are formed around the formers 44 with the end portions 42 creasing primarily along the other dashed slits 22, so that the end portions 42 form hexagonal sleeves 48 around the tabs 16. The formers are then withdrawn from the sleeves 42 leaving the circuit board 32 permanently deformed as shown in FIG. 9.

It will seen from FIGS. 8 and 9 that, as the end portions 42 of the circuit board 32 are formed around the formers 44, the slits 20 open up and the main portions 40 of the six ribs 21 separate from one another leaving large gaps 49 between adjacent main portions 40. The circuit board 32 therefore forms an open skeleton on which the LEDs 34 and tracks 28 are mounted.

In an optional step, before or after the bending step, the circuit board 32 may be coated in an electrically-insulating lacquer after masking the light-emitting portions of the LEDs 34 and the connecting portions 35.

In order to complete the electric lamp 10, plastics material 50 is moulded around the sleeves 48, tabs 16 and inclined portions 52 of the ribs 21 and into a pair of end caps 54, while leaving the tips of the terminals 35 exposed, as shown in FIGS. 11-13. If desired, further plastics material 56 may be applied to the outwardly facing faces of the main portions 40 of the ribs 21 for example by moulding the material 56 directly onto the main portions 40 (provided that the light-emitting portions of the LEDs 34 are masked) or by moulding separate elements which are then attached to the main portions of the ribs 21. If such further plastics material 56 is employed, it preferably has high thermal conductivity and emissivity.

It will be appreciated that, when the electric lamp 10 is fitted to a complementary light fitting and electricity of the appropriate current and polarity is supplied via the terminals 35, the LEDs 34 will light up, the light radiation pattern of the whole electric lamp 10 depending, of course, on the light radiation pattern of each LED 34. As can be seen from FIG. 12, the LEDs 34 are regularly arranged along the axis 60 of the lamp 10, with the optical axes 61 of the LEDs 34 at right angles to the lamp axis 60. Also, as can be seen from FIG. 13, the LEDs 34 are regularly arranged around the axis 60 of the lamp 10, with the optical axes 61 of the LEDs 34 equiangularly spaced.

The LEDs 34 will generate heat, some of which will be conducted away by the main portions 40 of the ribs 21. The main portions 40 of the ribs 21 can then dissipate the heat to the ambient air, particularly from the inwardly-facing faces of the main portions 40. As can be seen particularly in FIG. 13, the ambient air can freely travel through the gaps 49 between adjacent main portions 40 of the ribs 21 into and out of the space surrounded by the main portions 40 of the ribs 21.

In the manufacture of the second embodiment of electric lamp 10 (FIGS. 20-21) emulating a conventional GLS bulb, a blank 12 (FIG. 14) is employed, again comprising a flat sheet of aluminium having a thickness of, for example, 1 to 2 mm and to each face of which is bonded an electrically-insulating layer of polyethylene terephthalate film. The blank 12 is cut to have: a generally-rectangular rib-forming portion 13; a tip-forming portion 15 at one end of the rib-forming portion 13; a generally-rectangular sleeve-forming portion 17 at one end of the rib-forming portion 13; and a generally-rectangular tab 16 to one side of the sleeve-forming portion 17. The sleeve-forming portion 17 is equally subdivided by nine parallel dashed slits 22 into ten connected portions. A further dashed slit 23 is formed between the tab 16 and the sleeve-forming portion 17. The rib-forming portion 13 is also subdivided by nine continuous slits 20 into ten ribs 21. However, the slits 20 are not straight but instead deviate so that each rib 21 has a wider half 21w and a narrower half 21n, with the wider half 21w of each rib 21 being adjacent the narrower half or halves 21n of the adjacent rib(s). The edges of the blank 12 are shaped so that the outermost two ribs 21 have the same shape as the other eight ribs 21. The tip-forming portion 15 is notched along the end edge of the blank 12 so that a respective tapering tip 19 is provided for each rib 21. The roots of the notches stop short of the adjacent ends of the slits 20 so that the tips 19 are joined together.

Holes, as shown in FIG. 1 for the first embodiment, are formed in the blank 12 at the locations of the required vias. The holes are lined with insulating sleeves as described above with reference to FIG. 2. Copper tracks 28 are then placed on the blank 12 in the manner described above with reference to FIGS. 3A-B. Via rivets 30 are then fitted in the manner described above with reference to FIG. 4. For reasons of simplicity, the copper tracks 28 and rivets 30 are shown only in FIGS. 14-15 of the drawings of the second embodiment. The copper tracks 28 on the reverse side of the blank 12 are shown in dashed lines.

Referring to FIG. 15, the assembly of the circuit board 32 is completed by soldering a number of electrical components onto the blank 12. The components include ten rectangular surface-mount multi-junction LED chips 34 which are connected between portions of copper tracks on each of the wider halves 21w of the ribs 21, and one or more semiconductor chips 37 which are connected to copper pads on the tab 16. Other discrete components may also be fitted to the copper tracks. Thermally conductive paste or pads may be placed between the components 34,37 and the circuit board 32. The components 34,37 are preferably soldered using a wave-soldering technique. At this stage of the manufacture, the circuit board 32 may be tested by connecting an electrical supply to the terminal pads (not shown) on the tab 16.

The chips 37 may be arranged to control the current supplied to the LED chips 34 and to serve other functions. The copper tracks may connect the LED chips 34 to the chips 37 in any desired arrangement, for example driving all of the LED chips 34 in series with a single current controller, driving all of the LED chips 34 in parallel with a single current controller, or driving each LED chip 34 with its own respective current controller.

It will be noted that the manufacture of the circuit board 32 so far, including completion of the electrical circuitry, has been done on the flat, so that highly automated techniques can readily be employed.

Referring now to FIG. 16, the circuit board 32 is then deformed in a press between suitable dies. The press creates a fold line 36 along the junction of the ribs 21 with the sleeve-forming portion 17. Also, the press deforms the narrower halves 21n of the ribs 21 into arcs, whereas the wider halves 21w of the ribs 21 remain planar. The tips 19 at the ends of the ribs 21 remain coplanar. The copper tracks and vias (not shown) on the circuit board 32 are arranged so that the copper tracks remain flat or are disposed on the insides of the folds or curves so that the tracks are not elongated during the bending process.

In the next step, a former 44 as shown in FIG. 19 is employed. The former 44 comprises a bar of decagonal cross-section, where the length of side of the decagon is slightly less than the spacing of the dashed slits 22 of the circuit board 32. A diametric slot 46 is formed in one end of the former 44 and has a width slightly larger than the thickness of the circuit board 32. The slot 46 is relieved (at 47) so as not to foul the semiconductor chips 37.

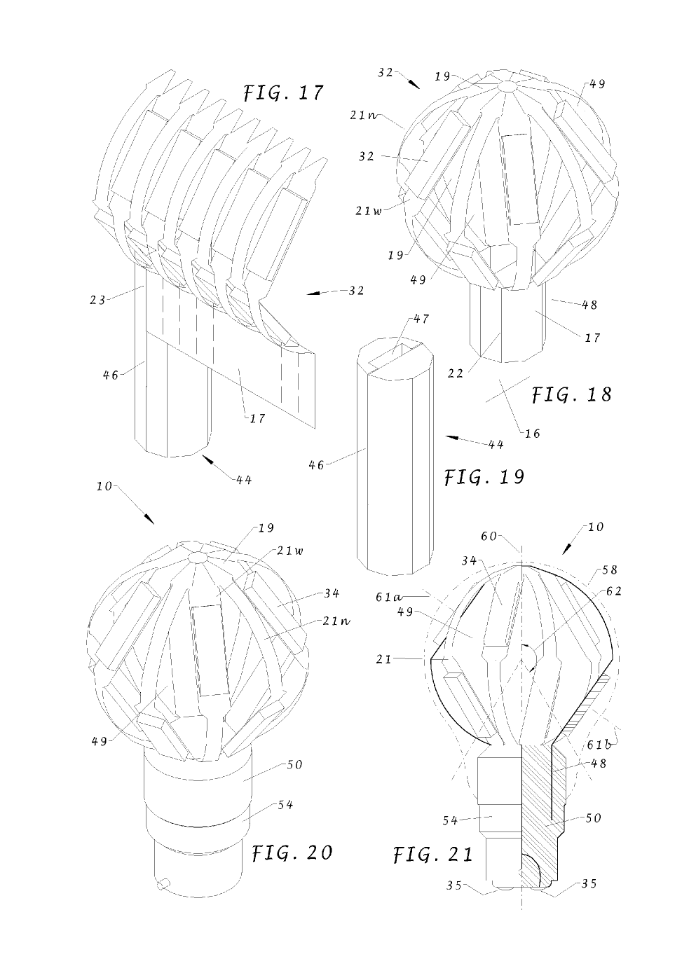

The tab 16 of the circuit board 32 is fitted into the slot 46 of the former 44 and the tab 16 is then folded, as shown in FIG. 17, relative to the remainder of the circuit board 32 through an angle of 108 degrees along the line of the dashed slits 23 between tab 16 and the sleeve-forming portion 17. These dashed slits 23 assist in producing a sharp fold. Then, the sleeve-forming portion 17 is formed around the former 44 with the sleeve forming portion 17 creasing primarily along the other dashed slits 22, so that the sleeve-forming portion 17 forms a decagonal sleeve 48 around the tab 16. The former 44 is then withdrawn from the sleeve 42 leaving the circuit board 32 permanently deformed as shown in FIG. 18.

It will seen from FIGS. 17 and 18 that, as the sleeve-forming portion 42 of the circuit board 32 is formed around the former 44, the slits 20 between the ribs 21 open up leaving large gaps 49 between adjacent ribs 21 over most of their lengths. The circuit board 32 therefore forms an open skeleton on which the LED chips 34 and tracks are mounted. Furthermore, the notches between the tips 19 close up so that the tips 19 form a substantially continuous, generally frusto-conical surface.

In an optional step, before or after the bending steps, the circuit board 32 may be coated in an electrically-insulating lacquer after masking the light-emitting portions of the LED chips 34 and the pair of connecting pads (not shown) on the tab 16.

In order to complete the electric lamp 10, two terminals 35 are connected to the connecting pads on the tab 16, and then plastics material 50 is moulded around the sleeve 48 and tab 16 and into an end cap 54, while leaving the tips of the terminals 35 exposed, as shown in FIGS. 20-21. If desired, further plastics material may be applied to the outwardly facing faces of the ribs 21 for example by moulding the material directly onto the ribs 21 (provided that the light-emitting portions of the LED chips 34 are masked) or by moulding separate elements which are then attached to the ribs 21. If such further plastics material is employed, it preferably has high thermal conductivity and emissivity.

It will be appreciated that, when the electric lamp 10 is fitted to a complementary light fitting and electricity of the appropriate current and polarity is supplied via the terminals 35, the LEDs 34 will light up, the light radiation pattern of the whole electric lamp 10 depending, of course, on the light radiation pattern of each LED chips 34.

It should be noted, however, that the ten LED chips 34 are equiangularly spaced around the axis 60 of the lamp 10, with the five LED chips 34 further from the cap 54 having their optical axes 61a inclined at an angle of about 45 degrees to the lamp axis 60 in one direction, and with the other five LED chips 34 nearer to the cap 54 having their optical axes inclined at an angle of about 45 degrees in the opposite direction. Therefore, with an appropriate radiation pattern for the LED chips 34, an approximately uniform radiation pattern for the lamp 10 as a whole can be achieved over a radiation half-angle 62 (see FIG. 21) of 150 degrees or more.

The LEDs 34 will generate heat, some of which will be conducted away by the ribs 21. The ribs 21 can then dissipate the heat to the ambient air, particularly from the inwardly-facing faces of the ribs 21. As can be seen particularly in FIG. 21, the ambient air can freely travel through the gaps 49 between adjacent ribs 21 into and out of the space surrounded by the ribs 21.

It will also be noted from FIG. 21 that the ribs 21 and LED chips 34 lie within the envelope (as indicated by the dot-dash line 58) of a conventional GLS light bulb.

The manufacture of a third embodiment of electric lamp 10 emulating a GU10 spot lamp will now be described with reference to FIGS. 22 to 26. The manufacturing techniques are similar to those employed in the first and second embodiments, and the third embodiment will therefore be described only briefly.

A blank 12, as shown in FIG. 22, of aluminium covered with insulating layers is cut and slit, and copper tracks and vias (not shown) are applied and formed as necessary. While the blank is still in the flat, six LEDs 34 and a control chip 37 are wave-soldered to the blank to form a circuit board 32 as shown in FIG. 23. The circuit board 32 is then deformed as shown in FIG. 24, with the portions of the circuit board 32 on which the LEDs 34 and chip 37 are mounted remaining flat. The circuit board 32 is then formed around a hexagonal former (not shown) to produce a sleeve 48, as shown in FIG. 25, from which six ribs 21 radiate and then turn back on themselves to portions on which the LEDs 34 are mounted, the ribs 21 terminating in a short hexagonal collar 64. The optical axes 61 of the LEDs 34 converge to a point lying on the axis 60 of the sleeve 48. A pair of terminals 35 is connected to the circuit board 32. A plastics cap 54 is then moulded around the terminals 35 and sleeve 48 to form a lamp 10 as shown in FIG. 26.

The manufacture of a fourth embodiment of electric lamp 10 emulating a conventional 12 V 21/5 W automotive brake- and tail-light bulb will now be described with reference to FIGS. 27-31. The manufacturing techniques are similar to those employed in the first and second embodiments, and the fourth embodiment will therefore be described only briefly.

A generally L-shaped blank 12 of aluminium, as shown in FIGS. 27A-B, is cut. One limb 66 of the L-shape is covered with insulating layers 68, as shown by crosshatching, except for small regions 70 aligned on either side of the blank 12. The other limb 72 of the L-shape is not covered with insulating layers. Via holes 24,74 are formed in the blank 12. The via holes 24 are fitted with insulating sleeves (not shown), except for a hole 74 in the uninsulated regions 70. Copper tracks 28 are formed on the blank 12 as shown in FIGS. 27A-B.

Via rivets 30,30A,82 are fitted to the holes 24, including an earthing via rivet 30A which is fitted to the hole 74 and connects its respective track to the aluminium of the blank 12. Also, an electrically-insulating disc 76 with a pair of through holes is fitted to a tab portion 78 of the blank adjacent the root portion 80 of the L-shape and held in place by a pair of connecting rivets 82, as shown in FIGS. 28A-B. A single junction LED 34 and a current control chip 37 are placed on the blank 12, and the whole assembly is then wave soldered. The current control chip 37 and copper tracks 28 are configured so that: (a) when a supply voltage of about 12V is connected between one of the connecting rivets 30B and the aluminium of the blank 12, a relatively low constant current passes through the LED 34 so that is produces light of a similar brightness to a 5 W tungsten filament bulb; (b) when the supply voltage is connected between the other connecting rivet 30B and the aluminium of the blank 12, a higher constant current passes through the LED 34 so that is produces light of a similar brightness to a 21 W tungsten filament bulb; and (c) when the supply voltage is connected between both connecting rivets 30B and the aluminium of the blank 12, an even higher constant current passes through the LED 34 so that is produces light of a similar brightness to both filaments of a 21/5 W tungsten filament bulb. The circuit board 32 may be tested at this stage.

The circuit board 32 is then permanently deformed as shown in FIGS. 29A-B. In particular, the tab portion 78 is bent fairly sharply through a right-angle relative to the root portion 80 in a first direction. The copper tracks 28 are on the inside of this bend so that they are not elongated by the bending process. The limb 66 is bent gently through an angle of about 20 degrees relative to the root portion 80 in a second opposite direction. The copper tracks 28 are on the outside of this bend, but the bending is sufficiently gentle that the tracks are not elongated so greatly that they break. The limb 66 is also bent through an angle of about 110 degrees in the first direction to either side of the LED 34. The copper tracks 28 are on the inside of these bends so that they are not elongated by the bending process. The other limb 72 is also punched to form a pair of dimples 84 on one face of the limb 72 and protruding pins 86 on the other face of the limb 72.

The bare aluminium limb 72 is then rolled into a cylindrical sleeve 48, as shown in FIGS. 30A-B, with the axis 60 of the sleeve 48 being coaxial with the LED 34 and the insulating disc 74. It will therefore be appreciated that the resulting lamp 10 can simply be arranged to emulate a conventional 12 V 21/5 W automotive brake- and tail-light bulb lying within the envelope (as indicated by the dot-dash line 58 in FIG. 31) of a conventional BAY15D light bulb.

Referring now to FIGS. 32 to 34, a fifth embodiment of electric lamp 10 is shown, emulating a conventional GLS bulb. As shown in FIG. 32, the main components of the bulb 10 are a base shell half 88, a top shell half 90, a bayonet or Edison screw (BC or ES) connector cap 54, a printed circuit board 92 populated with various electrical components 37, a pair of wire guides 94,96, ten LEDs 34 and a plug 98. Interconnecting wires between the circuit board 92 and the LEDs 34 are not shown in FIGS. 32 to 34.

The shell halves 88,90 are thin-wall die-castings of aluminium. As shown in FIG. 34, the shell halves 88,90 together form a pear-shaped shell 100, with the top shell half 90 being approximately hemi-spherical and forming the rounded end of the pear shape, and with the base shell half 88 forming the remainder of the pear shape. The base shell half 88 has an open ended neck 102 which is fitted to the connector cap 54. Each shell half 88,90 is formed with five equiangularly-spaced flat-bottomed depressions 104 in its outer surface, with the depressions 104 in the base shell half 88 being inclined at an angle of about 45 degrees to the cap 54 end of the shell 100, and with the depressions 104 in the top shell half 90 being inclined at an angle of about 45 degrees to the rounded end of the shell 100. The flat bottom of each depression 104 is formed with a through-hole 106 covering only a small proportion of the area of the flat bottom. Between each adjacent pair of depressions 104 in each shell half 88,90, a respective generally-triangular through-hole 108 is formed for ventilation purposes. At the rounded end of the top shell half 90A, a central through-hole 110 is also formed, for receiving the plug 98. The plug 98 is formed with an array of ventilation holes. Adjacent their mating edges, the shell halves 88,90 have cooperating ribs 112 which can be clinched, crimped or punched so that they interlock to hold the shell halves 88,90 together. Between the ribs 112, the mating edges are formed with notches 114 (FIG. 32) which align in pairs when the shell halves 88,90 are connected together so as to form further through holes 116 (FIG. 34) in the shell 100.

Opposite their light-emitting faces, the LEDs 34 have flat rear faces corresponding in outline to the shape of the flat bottoms of the depressions 104 in the shells 98,100. The rear faces of the LEDs 34 also have protruding electrical connectors 118 which align with the holes 106 in the depressions 104 when the LEDs are fitted to the shell 100.

The printed circuit board 92 has a pair of input terminals 120 adjacent its lower end for connection to mains supply contacts of the connector cap 54. Nearer its upper end the printed circuit board 92 has a pair of output terminals 122 for connection to a series circuit of the ten LEDs. The printed circuit board 92 and its components 37 may be contrived to perform any required functions for driving the LEDs 34 including voltage step-down, current regulation, temperature compensation, flashing and dimming.

Each wire guides 94,96 is a press- or click-fit into the respective shell half 88,90 adjacent its mating edge. Each wire guide 94,96 is an annular moulded plastic part with grooves into which lengths of wire (not shown) are press-fitted. The wires of each guide 94,96 may be arranged, for example, to connect the five LEDs 34 of the respective shell half in series between a respective output terminal 122 of the printed circuit board 92 and a wire of the other guide 96,94.

In one example of a method of assembly of the lamp 10 of FIGS. 32 to 34, the neck of the base shell half 88 is fitted into the connector cap 54 and is secured thereto, for example by bonding, clinching, crimping or riveting. The circuit board 92 is then inserted into the base shell half 88 and its input terminals 120 are connected to the supply contacts of the connector cap 54 by soldering. Resin or silicone is then deposited into the connector cap 54 to hold the circuit board 92 steady. Each wire guide 94,96 is then press- or click-fitted to its respective shell half 88,90; the LEDs 34 are bonded by their flat rear faces to the flat bottoms of the depressions 104 with their connectors 118 protruding into the holes 106, and the wires of the wire guides 94,96 are electrically connected to the LED connectors 188 by soldering. The shell halves 88,90 are then offered up to each other, and the wires of the wire guides 94,96 are connected to each other and to the output terminals 122 of the circuit board 92 by soldering. The shell halves 88,90 are then mated and mechanically fixed to each other by inserting tools into each adjacent pair of the holes 116 and clinching the mating ribs 112 situated between those holes 116. The plug 98 is then fitted to the hole 110.

It will be appreciated that the shell halves 88,90 and connector cap 54 can form a very rigid structure. The flat rear faces of the LEDs 34 and the flat bottoms of the depressions 104 of the shell 100 provide a good thermal path from the LEDs 34 to the thermally conducting shell 100. The shell 100 has a substantial external exposed area from which heat can be dissipated. Furthermore, the shell 100 has an even greater exposed area internally, and the holes 108, 116 permit ambient air to circulate in and out of the shell 100 to cool the internal surface.

It will be appreciated that many modifications and developments may be made to the lamp 10 of FIGS. 32 to 34 and its method of manufacture. For example, the final soldering stage may be carried out using a soldering tool inserted through the aperture 116 in the top shell half 90 after the shell halves 88,90 have been mechanically connected together. The circuit board 92 and its components 37, and any other exposed electrical parts may be potted in resin or otherwise insulated. Barbed push-fit connections may be provided between the circuit board 92 and the connector cap 54 and/or between the wire guides 94,96 and the circuit board 92 and/or between the wire guides 94,96 and the LEDs 34 so as to reduce the amount of soldering or obviate the need for any soldering. The wire guides and their wires may be replaced by conductors stamped and pressed out of sheet metal and then over-moulded with plastics material. The body of the connector cap 54 (particularly if it is an ES cap) may be insulated from the base shell half 88, for example using an insert-moulded plastic part in the cap body. Alternatively, the body of the connector cap 54 (particularly if it is a BC cap) may be integrally formed with the base shell half 88.

It should be noted that the embodiments of the invention have been described above purely by way of example and that many modifications and developments may be made thereto within the scope of the present invention.

1-47. (canceled)

48. An electric lamp comprising: a plurality of electrically-powered light sources; at least one electrical connector electrically connected to the light sources; and a structure to which the light sources are mounted with different orientations and to which the connector(s) is/are mounted; wherein: the structure has the form of an open, three-dimensional arrangement of interconnected mounting portions with gaps therebetween so that ambient air can pass through the gaps and circulate through the arrangement of mounting portions; the light sources are mounted in thermal contact with the mounting portions; and the mounting portions are thermally conductive so that they can dissipate heat away from the light sources.

49. The lamp as claimed in claim 48, wherein: at least some of the mounting portions carry electrically-conductive tracks connecting at least in part the light sources to the electrical connector(s).

50. The lamp as claimed in claim 48, wherein: the structure has the form of an open, three-dimensional skeleton.

51. The lamp as claimed in claim 48, wherein: the structure has the form of a shell with apertures therethrough.

52. The lamp as claimed in claim 51, wherein: the shell is constructed from a plurality of separately formed shell portions.

53. The lamp as claimed in claim 48, wherein: each of the light sources has a rear face which is substantially flat and is mounted on a respective substantially flat part of such a mounting portion.

54. The lamp as claimed in claim 48, wherein: the lamp has an axis; and the light sources are substantially regularly arranged around the axis.

55. The lamp as claimed in claim 48, wherein: the light sources are LEDs.

56. The lamp as claimed in claim 48, wherein: the lamp is devoid of an enclosure enveloping the light sources.

57. A method of manufacture of an electric lamp comprising the steps of: providing at least two shell portions and a circuit board; assembling the shell portions and the circuit board so that: the shell portions are mechanically connected to each other to form a hollow shell, the circuit board is contained within the shell, and an electrical input to the circuit board is externally accessible; attaching a plurality of light emitting devices to the shell; and electrically connecting the light emitting devices to the circuit board.

58. The method as claimed in claim 57, wherein: the shell portions are formed by die casting metal.

59. The method as claimed in claim 57, wherein: the shell portions are formed by pressing and forming sheet metal.

60. A method of manufacture of an electrical device, comprising the steps of: providing a flat, plastically-deformable circuit board; then mounting at least one electrical component on the flat circuit board and electrically connecting the component(s) in a circuit; and then plastically deforming the circuit board so that it is no longer flat, and the component(s) remain(s) mounted on the circuit board and electrically connected in the circuit.

61. The method as claimed in claim 60, wherein: the circuit board has a plurality of deformable, electrically-conductive tracks formed on a plastically-deformable substrate; and the mounting and connecting step includes physically and electrically connecting the component or at least one of the components to the tracks.

62. The method as claimed in claim 61, wherein: the tracks are disposed on the substrate so that none of the tracks undergoes sufficient elongation to cause the tracks to break during the deforming step.

63. The method as claimed in claim 60, wherein: the circuit board, or at least the substrate thereof, is thermally conductive.

64. The method as claimed in claim 60, wherein: during the deforming step: a portion of the circuit board is folded or bent in a first direction; and then a portion of the circuit board is folded or bent in a second direction not parallel to the first direction.

65. The method as claimed in claim 60, wherein: the circuit board is formed with a plurality of slits between portions of the circuit board; and during the deforming step, the widths of the slits increase so that after the deforming step those portions of the circuit board form an open skeleton.

66. The method as claimed in claim 65, wherein: after the deforming step, the open skeleton is a three-dimensional skeleton.

67. The method as claimed in claim 60, wherein: during the deforming step, a portion of the circuit board is bent so that it becomes substantially tubular.
